(19) United States
(12) Patent Application Publication
(10) Pub. No.: US 2018/0323039 A1
(43) Pub. Date: Nov. 8, 2018

(54) ACTIVE FAR EDGE PLASMA TUNABILITY

(71) Applicant: Applied Materials, Inc., Santa Clara, CA (US)

(72) Inventors: Hyungje WOO, San Jose, CA (US); Juan Carlos ROCHA-ALVAREZ, San Carlos, CA (US); Chen-An CHEN, San Jose, CA (US); Ajit BALAKRISHNA, Santa Clara, CA (US)

(21) Appl. No.: 15/961,282

(22) Filed: Apr. 24, 2018

Related U.S. Application Data
(60) Provisional application No. 62/502,457, filed on May 5, 2017.

(51) Int. Cl. H01J 37/32; H01L 21/683

(52) U.S. Cl. CPC H01J 37/3299; H01L 21/6833; H01J 37/32174; H01J 2237/3323; H01J 2237/3344; H01J 2237/3321; H01J 37/32541

(57) ABSTRACT

The present disclosure relates to methods and apparatuses for controlling a plasma sheath near a substrate edge. The method includes changing the voltage/current distribution across a central electrode and an annular electrode within the substrate assembly to facilitate the spatial distribution of the plasma across the substrate. The method also includes applying a first radio frequency power to a central electrode embedded in a substrate support and applying a second radio frequency power to an annular electrode embedded in the substrate support at a location different than the central electrode. The annular electrode is spaced from the central electrode and circumferentially surrounds the central electrode. The method also includes monitoring parameters of the first and second radio frequency powers and adjusting one of the first and second radio frequency powers based on the monitored parameters.

### CROSS-REFERENCE TO RELATED APPLICATIONS

This application claims benefit of U.S. Appl. No. 62/502,457, filed May 5, 2017, which is herein incorporated by reference.

### BACKGROUND

### Field

Embodiments disclosed herein generally relate to an apparatus and method for plasma tuning near a substrate edge.

### Description of the Related Art

In the manufacture of integrated circuits and other electronic devices, plasma processes are often used for deposition or etching of various material layers. Plasma-enhanced chemical vapor deposition (PECVD) process is a chemical process wherein electro-magnetic energy is applied to at least one precursor gas or precursor vapor to transform the precursor into a reactive plasma. Plasma may be generated inside the processing chamber, e.g., in-situ, or in a remote plasma generator that is remotely positioned from the processing chamber. This process is widely used to deposit materials on substrates to produce high-quality and high-performance semiconductor devices.

In the current semiconductor manufacturing industry, transistor structures have become increasingly complicated and challenging as feature size continues to decrease. To meet processing demands, advanced processing control techniques are useful to control cost and maximize substrate and die yield. Normally, the dies at the edge of the substrate suffer yield issues such as contact via misalignment, and poor selectivity to a hard mask. On the substrate processing level, there is a need for advancements in process uniformity control to allow fine, localized process tuning as well as global processing tuning across the whole substrate.

Therefore, there is a need for methods and apparatus to allow fine, localized process tuning at the edge of the substrate.

### SUMMARY

Embodiments disclosed herein generally relate to apparatuses of and methods for plasma tuning near a substrate edge. In one implementation, a method for tuning a plasma in a chamber is disclosed and includes applying a first radio frequency power to a central electrode embedded in a substrate support and applying a second radio frequency power to an annular electrode embedded in the substrate support at a location different than the central electrode. The annular electrode is spaced from the central electrode and circumferentially surrounds the central electrode. The method also includes monitoring parameters of the first and second radio frequency powers and adjusting one of the first and second radio frequency powers based on the monitored parameters.

In another implementation, a method for tuning a plasma in a chamber is disclosed and includes applying a first radio frequency power to a central electrode embedded in a substrate support and applying a second radio frequency power to an annular electrode embedded in the substrate support at a location different than the central electrode. The annular electrode is spaced from the central electrode and circumferentially surrounds the central electrode. The method also includes monitoring parameters of the first and second radio frequency powers and adjusting both of the first and second radio frequency powers based on the monitored parameters.

In yet another implementation, a method for tuning a plasma in a chamber is disclosed and includes applying a first impedance, a first voltage, or a combination of the first impedance and voltage to a central electrode embedded in a substrate support and applying a second impedance, a second voltage, or a combination of the second impedance and voltage to an annular electrode embedded in the substrate support at a location different than the central electrode. The annular electrode circumferentially surrounds the central electrode. The method also includes monitoring one or more parameters of the first impedance, the second impedance, the first voltage, the second voltage, or any combination thereof and adjusting one or more of the first impedance, the second impedance, the first voltage, the second voltage, or any combination thereof based on the monitored parameters.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a cross-sectional view of a processing chamber, according to one or more embodiments.

FIG. 2 depicts a top perspective view of a substrate support assembly, according to one or more embodiments.

FIG. 3 depicts a partial perspective view of another substrate support assembly, according to one or more embodiments.

FIG. 4 depicts a partial perspective view of another substrate support assembly, according to one or more embodiments.

### DETAILED DESCRIPTION

The present disclosure generally relates to methods of and apparatuses for controlling a plasma sheath near a substrate edge. Changing the voltage/current distribution across a central electrode and an annular electrode with in the substrate assembly facilitates the spatial distribution of the plasma across the substrate. The method includes applying a first radio frequency power to a central electrode embedded in a substrate support, applying a second radio frequency power to an annular electrode embedded in the substrate support at a location different than the central electrode, wherein the annular electrode circumferentially surrounds the central electrode, monitoring parameters of the first and second radio frequency powers, and adjusting one or both of the first and second radio frequency powers based on the monitored parameters.

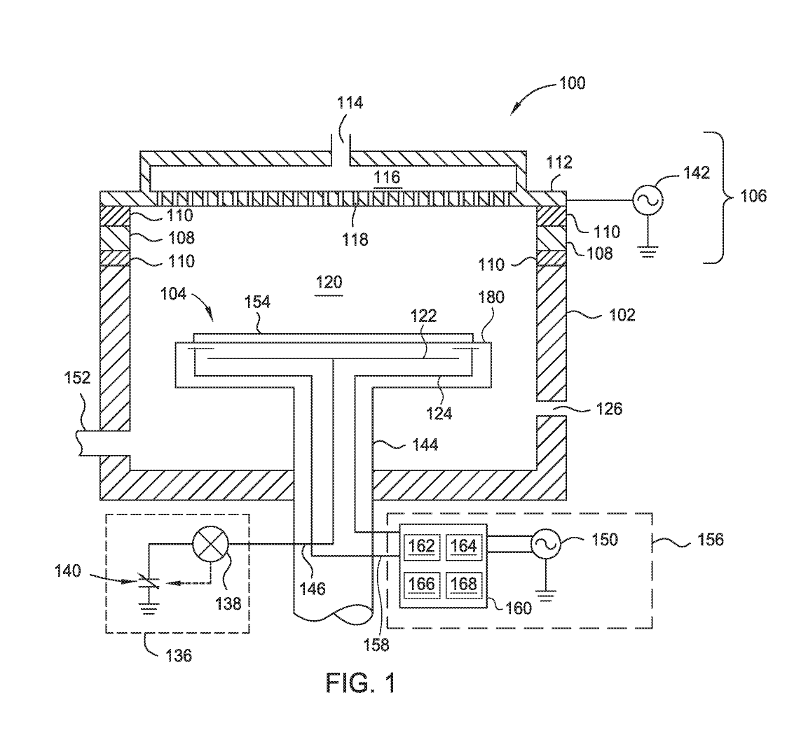

FIG. 1 is a cross sectional view of a processing chamber 100, according to one or more embodiments. In one or more examples, the processing chamber 100 is a deposition chamber, such as a plasma-enhanced chemical vapor deposition (PECVD) chamber, suitable for depositing one or more materials on a substrate, such as a substrate 154. In other examples, the processing chamber 100 is an etch chamber suitable for etching a substrate, such as the substrate 154. Examples of processing chambers that may be adapted to benefit from exemplary aspects of the disclosure are Producer® Etch Processing Chamber, and Precision™ Processing Chamber, commercially available from Applied Materials, Inc., located in Santa Clara, Calif. It is contemplated that other processing chambers, including those from other manufacturers, may be adapted to benefit from aspects of the disclosure.

The processing chamber 100 may be used for various plasma processes. In one aspect, the processing chamber 100 may be used to perform dry etching with one or more etching agents. For example, the processing chamber may be used for ignition of plasma from a precursor, such as one or more fluorocarbons (e.g., CF₄ or C₂F₆), O₂, NF₃, or any combination thereof. In another implementation the processing chamber 100 may be used for PECVD with one or more chemical agents.

The processing chamber 100 includes a chamber body 102, a lid assembly 106, and a substrate support assembly 104. The lid assembly 106 is positioned at an upper end of the chamber body 102. The lid assembly 106 and the substrate support assembly 104 may be used with any processing chamber for plasma or thermal processing. Other chambers available from any manufacturer may also be used with the components described above. The substrate support assembly 104 is disposed inside the chamber body 102, and the lid assembly 106 coupled to the chamber body 102 and enclosing the substrate support assembly 104 in a processing volume 120. The chamber body 102 includes a slit valve opening 126 formed in a sidewall thereof. The slit valve opening 126 is selectively opened and closed to allow access to the interior volume 120 by a substrate handling robot (not shown) for substrate transfer.

An electrode 108 is disposed adjacent to the chamber body 102 and separating the chamber body 102 from other components of the lid assembly 106. The electrode 108 may be part of the lid assembly 106, or may be a separate side wall electrode. The electrode 108 may be an annular or ring-like member, such as a ring electrode. The electrode 108 may be a continuous loop around a circumference of the processing chamber 100 surrounding the processing volume 120, or may be discontinuous at selected locations, if desired. The electrode 108 may also be a perforated electrode, such as a perforated ring or a mesh electrode. The electrode 108 may also be a plate electrode, for example, a secondary gas distributor.

An isolator 110 contacts the electrode 108 and separates the electrode 108 electrically and thermally from a gas distributor 112 and from the chamber body 102. The isolator 110 may be made from or contain one or more dielectric materials. Exemplary dielectric materials can be or include one or more ceramics, metal oxides, metal nitrides, metal oxynitrides, silicon oxides, silicates, or any combination thereof. For example, the isolator 110 may be formed from or contain aluminum oxide, aluminum nitride, aluminum oxynitride, or any combination thereof. The gas distributor 112 features openings 118 for admitting process gas into the processing volume 120. The process gases may be supplied to the processing chamber 100 via one or more conduits 114, and the process gases may enter a gas mixing region 116 prior to flowing through one or more openings 118. The gas distributor 112 may be coupled to an electric power source 142, such as an RF generator. DC power, pulsed DC power, and pulsed RF power may also be used.

The substrate support assembly 104 includes a substrate support 180 that holds or supports one or more substrates 154 for processing. The substrate support 180 is coupled to a lift mechanism through a shaft 144, which extends through a bottom surface of the chamber body 102. The lift mechanism may be flexibly sealed to the chamber body 102 by a bellow that prevents vacuum leakage from around the shaft 144. The lift mechanism allows the substrate support assembly 104 to be moved vertically within the chamber body 102 between a lower transfer position and a number of raised process positions.

The substrate support 180 may be formed from or contain a metallic or ceramic material. Exemplary metallic or ceramic materials can be or include one or more metals, metal oxides, metal nitrides, metal oxynitrides, or any combination thereof. For example, the substrate support 180 may be formed from or contain aluminum, aluminum oxide, aluminum nitride, aluminum oxynitride, or any combination thereof. A central electrode 122 is coupled to the substrate support assembly 104. The central electrode 122 may be embedded within the substrate support 180 and/or coupled to a surface of the substrate support 180. The central electrode 122 may be a plate, a perforated plate, a mesh, a wire screen, or any other distributed arrangement.

The central electrode 122 may be a tuning electrode, and may be coupled to a tuning circuit 136 by a conduit 146, for example a cable having a selected resistance, such as 50Ω, disposed in a shaft 144 of the substrate support assembly 104. The tuning circuit 136 may include an electronic sensor 138 and an electronic tuner or controller 140, which may be a variable capacitor. The electronic sensor 138 may be a voltage or current sensor, and may be coupled to the electronic tuner or controller 140 to provide further control over plasma conditions in the processing volume 120. In one or more aspects, the electronic tuner or controller 140 can be used to modulate impedance on the central electrode 122.

An annular electrode 124 is coupled to the substrate support assembly 104. The annular electrode 124 may be embedded within the substrate support 180 and/or coupled to a surface of the substrate support 180. The central electrode 122 is disposed below an upper portion of the annular electrode 124. In some examples, the annular electrode 124 is a bias electrode and/or an electrostatic chucking electrode. The annular electrode 124 may be coupled to a tuning circuit 156 by one or more cables or conduits 158 which are disposed in the shaft 144 of the substrate support assembly 104. The tuning circuit 156 may include to an electric power source 150 and a process controller 160 electrically coupled to the annular electrode 124.

The electric power source 150 may illustratively be a source of electricity of up to about 1,000 W (but not limited to about 1,000 W) of RF energy at a frequency of, for example, approximately 13.56 MHz, although other frequencies and powers may be applied or otherwise provided as desired for particular applications. The electric power source 150 may be capable of producing either or both of continuous or pulsed power. In one or more examples, the bias source may be a direct current (DC) or pulsed DC source. In other examples, the bias source may be capable of providing multiple frequencies, such as 2 MHz and 13.56 MHz.

The process controller 160 may include a DC power supply 162, an RF generator 164, one or more electronic sensors 166, and one or more electronic tuners or controllers 168. The DC power supply 162 may supply voltage to the annular electrode 124 and the RF generator 164 may apply the RF frequency during the plasma process. The DC power supply 162 may supply and control a voltage from 0 V to about 1,000 V. In one or more aspects, the electronic tuner or controller 168 can be used to modulate impedance on the annular electrode 124. For example, the electronic tuner or controller 168 can be used to control impedance with a variable capacitor such that about 5% to about 95% of the impedance is controlled to the annular electrode 124. In some aspects, the electronic sensor 166 may be a voltage or current sensor, and may be coupled to the electronic tuner or controller 168 to provide further control over plasma conditions in the processing volume 120.

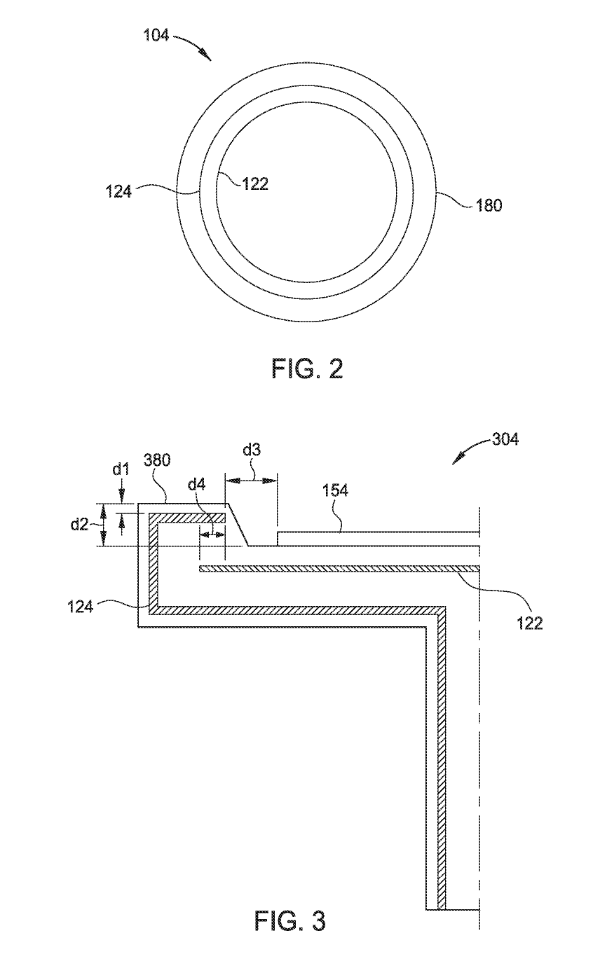

FIG. 2 illustrates a top view of the substrate support assembly 104, according to one or more embodiments. The central electrode 122 and the annular electrode 124 are coupled to separate power sources as shown in FIG. 1. The central electrode 122 and the annular electrode 124 may independently be embedded or partially embedded in the substrate support 180. The central electrode 122 may be a plate, a perforated plate, a mesh, a wire screen, or any other distributed arrangement. The central electrode 122 is formed from or contains one or more electrically conductive metals or materials, such as, aluminum, copper, alloys thereof, or any mixture thereof. The annular electrode 124 may be a circular ring. However, other shapes are contemplated. The annular electrode 124 may be continuous or have spaces throughout. In some implementations, the central electrode 122 and the annular electrode 124 are cathodes.

In one or more examples, the central electrode 122 has a greater surface area than the annular electrode 124. In some examples, the annular electrode 124 has a greater diameter than the central electrode 122. The annular electrode 124 is formed from or contains one or more electrically conductive metals or materials, such as, aluminum, copper, alloys thereof, or any mixture thereof. The annular electrode 124 may surround the central electrode 122. In one implementation, the annular electrode 124 at least partially overlaps laterally with the central electrode 122. In one or more implementations, the annular electrode 124 is laterally adjacent the central electrode 122 and can be on the same plane or different planes.

Each of the central electrode 122 and the annular electrode 124 is independently powered and controlled. The power distribution to the central electrode 122 is a separate path than to the annular electrode 124. As such, the travel path of the electrical current may be spilt into separate sections facilitating a wider distribution thereby improving process uniformity. Additionally, the vertical separation between the central electrode 122 and the annular electrode 124 extends the coupling power and increases the process uniformity.

In some implementations, the central electrode 122 may function as a chucking electrode while also functioning as a first RF electrode. The annular electrode 124 may be a second RF electrode that together with the central electrode 122 tunes the plasma. The central electrode 122 and the annular electrode 124 may produce power at the same frequency or at different frequencies.

In one or more embodiments, the RF power from one or both the central electrode 122 power source and the annular electrode 124 power source may be varied in order to tune the plasma. For example, a sensor (not shown) may be used to monitor the RF energy from one or both of the central electrode 122 and the annular electrode 124. Data from the sensor device may be communicated and utilized to vary power applied to the RF power source for the central electrode 122 and/or the RF power source for the annular electrode 124.

In another embodiment, a first impedance and/or voltage is applied or otherwise provided to the central electrode 122, and independently, a second impedance and/or voltage is applied or otherwise provided to the annular electrode 124. Parameters of the first impedance and/or voltage and parameters of the second impedance and/or voltage can independently be monitored, controlled, and adjusted based on the monitoring parameters. Each of the first and/or second impedances can independently be increased and/or decreased, such as being modulated, in order to improve uniformity across the upper surface of the substrate. Also, each of the first and/or second voltages can independently be increased, decreased, modulated, or otherwise adjusted in order to improve the uniformity on the substrate surface.

In one or more examples, each of the first and/or second impedances and/or the first and/or second voltages can independently be modulated to decrease an in plane distortion (IPD) of the uniformity of the substrate surface by 40% or greater, relative to the IPD of the substrate surface prior to adjusting or modulating any of the impedances or voltages, without changing the profile. For example, each of the first and/or second impedances and/or the first and/or second voltages can independently be modulated to decrease the IPD of the substrate surface uniformity by about 50%, about 60%, about 70%, or greater, without changing the profile. In some examples, the IPD of the plasma uniformity can be reduced by about 40% to about 70% relative to the IPD of the substrate surface uniformity prior to adjusting or modulating any of the impedances or voltages, without changing the profile.

FIG. 3 depicts a partial perspective view of a substrate support assembly 304 that includes the substrate support 380, according to one or more embodiments. In this implementation, the substrate 154 is positioned or otherwise disposed above the central electrode 122 and below the upper portion of the annular electrode 124 and the central electrode 122 and the annular electrode 124 horizontally overlap each other. The annular electrode 124 is disposed laterally adjacent the substrate 154 within the substrate support 380, such that the annular electrode 124 circumferentially surrounds the central electrode 122.

As depicted in FIG. 3, the upper portion of the annular electrode 124 is embedded in to the substrate support 380 and is a distance d1 from the upper surface of the substrate support 380. In some examples, the distance d1 can be about 0.01 inches (in), about 0.03 in, or about 0.05 in to about 0.1 in, about 0.2 in, or about 0.3 in. For example, the distance d1 can be from about 0.01 in to about 0.3 in.

An upper portion of the substrate support 380 has a thickness of a distance d2 that is measured between the upper surface of the substrate support 380 and the surface of the substrate support 380 that the substrate 154 is disposed on. In some examples, this upper portion of the substrate support 380 is optional and therefore the distance d2 is 0. In other examples, the distance d2 can be about 0.01 in, about 0.05 in, or about 0.07 in to about 0.1 in, about 0.15 in, about 0.2 in, or about 0.25 in. For example, the distance d2 can be from about 0 in to about 0.25 in or from about 0.05 in to about 0.25 in.

A distance d3 is measured between the end of the upper portion of the annular electrode 124 and the edge of the substrate 154 disposed on the substrate support 380. In some examples, the distance d3 can be about 0.001 in, about 0.005 in, or about 0.007 in to about 0.1 in, about 0.15 in, about 0.2 in, or about 0.25 in. For example, the distance d3 can be from about 0.005 in to about 0.2 in. In the substrate support assembly 304, the central electrode 122 and the annular electrode 124 horizontally overlap each other by a distance d4. In some examples, the distance d4 can be about 0.001 in, about 0.005 in, or about 0.007 in to about 0.1 in, about 0.2 in, about 0.25 in, about 0.3 in, about 0.35 in, or about 0.4 in. For example, the distance d4 can be from about 0.001 in to about 0.35 in.

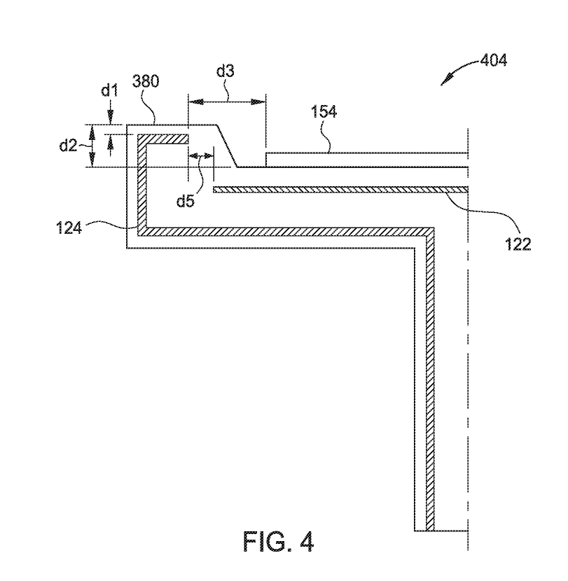

FIG. 4 depicts a partial perspective view of a substrate support assembly 404, according to one or more embodiments. In this implementation, instead of overlapping, a gap horizontally separates the central electrode 122 and the upper portion of the annular electrode 124 at a distance of d5. In some examples, the distance d5 can be about 0.001 in, about 0.005 in, or about 0.007 in to about 0.1 in, about 0.2 in, about 0.25 in, about 0.3 in, about 0.35 in, or about 0.4 in. For example, the distance d5 can be from about 0.001 in to about 0.35 in.

Similarly to the substrate support assembly 304, the substrate support assembly 404 includes the substrate support 380 such that the substrate 154 is positioned or otherwise disposed above the central electrode 122 and below the upper portion of the annular electrode 124. The annular electrode 124 is disposed laterally adjacent the substrate 154 within the substrate support 380, such that the annular electrode 124 circumferentially surrounds the central electrode 122. The values for the distances d1, d2, and d3 are the same for the substrate support assembly 404 as disclosed above for the substrate support assembly 304.

In another embodiment, the central electrode 122 and the upper portion of the annular electrode 124 do not overlap or have a gap therebetween (not shown). Instead, the central electrode 122 and the upper portion of the annular electrode 124 are horizontally flush or adjacent with each other. Therefore, the distance d4 is 0 for the substrate support assembly 304 and the distance d5 is 0 for the substrate support assembly 404.

In one implementation, the central electrode 122 is powered at the same time as the annular electrode 124. In one implementation, the central electrode 122 is on while the annular electrode 124 is off. In one implementation, the central electrode 122 is off while the annular electrode 124 is on. Modulating between powering the central electrode 122 and the annular electrode 124 facilitates control of plasma characteristics at the substrate 154 edge. Additionally, individually tuning the power source to each of the central electrode 122 and the annular electrode 124 results in increased or decreased plasma density. Changing the voltage/current distribution across the central electrode 122 and the annular electrode 124 facilitates the spatial distribution of the plasma across the substrate.

In one or more embodiments, a method for tuning a plasma in a chamber includes applying a first radio frequency power to the central electrode 122 and applying a second radio frequency power to the annular electrode 124. The method also includes monitoring parameters of the first and second radio frequency powers and either adjusting one of or both of the first and second radio frequency powers based on the monitored parameters.

In other embodiments, a method for tuning a plasma in a chamber includes applying a first impedance, a first voltage, or a combination of the first impedance and voltage to the central electrode 122 and applying a second impedance, a second voltage, or a combination of the second impedance and voltage to the annular electrode 124. The method also includes monitoring one or more parameters of the first impedance, the second impedance, the first voltage, the second voltage, or any combination thereof and adjusting one or more of the first impedance, the second impedance, the first voltage, the second voltage, or any combination thereof based on the monitored parameters.

Benefits of the present disclosure include increased control of plasma adjacent edges of a substrate. Increasing the plasma control results in increased plasma uniformity.

While the foregoing is directed to embodiments of the present invention, other and further embodiments of the invention may be devised without departing from the basic scope thereof, and the scope thereof is determined by the claims that follow.

1. A method for tuning a plasma in a chamber, comprising:
applying a first radio frequency power to a central electrode embedded in a substrate support;
applying a second radio frequency power to an annular electrode embedded in the substrate support at a location different than the central electrode, wherein the annular electrode circumferentially surrounds the central electrode;
monitoring parameters of the first and second radio frequency powers; and
adjusting one of the first and second radio frequency powers based on the monitored parameters.

2. The method of claim 1, wherein the first radio frequency power is applied by a first power source and the second radio frequency power is applied by a second power source.

3. The method of claim 1, wherein the central electrode is disposed below the annular electrode.

4. The method of claim 3, wherein the annular electrode partially overlaps the central electrode.

5. The method of claim 1, wherein applying the second radio frequency power to the annular electrode occurs at the same time as applying the first radio frequency power to the central electrode.

6. The method of claim 1, further comprising turning off the first radio frequency power, wherein the first radio frequency power is turned off before applying the second radio frequency power to the central electrode.

7. The method of claim 1, further comprising turning off the second radio frequency power, wherein the first radio frequency power is on.

8. The method of claim 1, further comprising turning off the first radio frequency power, wherein the first radio frequency power is turned off after applying the second radio frequency power to the central electrode.

9. A method for tuning a plasma in a chamber, comprising:
applying a first radio frequency power to a central electrode embedded in a substrate support;
applying a second radio frequency power to an annular electrode embedded in the substrate support at a location different than the central electrode, wherein the annular electrode circumferentially surrounds the central electrode;
monitoring parameters of the first and second radio frequency power; and
adjusting both of the first and second radio frequency powers based on the monitored parameters.

10. The method of claim 9, wherein the first radio frequency power is applied by a first power source and the second radio frequency power is applied by a second power source.

11. The method of claim 9, wherein the central electrode is disposed below the annular electrode.

12. The method of claim 11, wherein the annular electrode partially overlaps the central electrode.

13. The method of claim 9, wherein applying the second radio frequency power to the annular electrode occurs at the same time as applying the first radio frequency power to the central electrode.

14. The method of claim 9, further comprising turning off the first radio frequency power, wherein the first radio frequency power is turned off before applying the second radio frequency power to the central electrode.

15. The method of claim 9, further comprising turning off the second radio frequency power, wherein the first radio frequency power is on.

16. The method of claim 9, further comprising turning off the first radio frequency power, wherein the first radio frequency power is turned off after applying the second radio frequency power to the central electrode.

17. A method for tuning a plasma in a chamber, comprising:
applying a first impedance, a first voltage, or a combination of the first impedance and voltage to a central electrode embedded in a substrate support;
applying a second impedance, a second voltage, or a combination of the second impedance and voltage to an annular electrode embedded in the substrate support at a location different than the central electrode, wherein the annular electrode circumferentially surrounds the central electrode;
monitoring one or more parameters of the first impedance, the second impedance, the first voltage, the second voltage, or any combination thereof; and
adjusting one or more of the first impedance, the second impedance, the first voltage, the second voltage, or any combination thereof based on the monitored parameters.

18. The method of claim 17, wherein the first impedance, the second impedance, or a combination of the first and second impedances is modulated based on the monitored parameters.

19. The method of claim 17, wherein the first voltage, the second voltage, or a combination of the first and second voltages is modulated based on the monitored parameters.

20. The method of claim 17, decrease an in plane distortion (IPD) of a substrate surface by 40% or greater, relative to the IPD of the substrate surface prior to adjusting any one or more of the first impedance, the second impedance, the first voltage, the second voltage, or any combination thereof.
